(19) United States
(12) Patent Application Publication
(10) Pub. No.: US 2002/0162741 A1
(43) Pub. Date: Nov. 7, 2002

(54) Multi-material target backing plate

(75) Inventor: James Van Gogh, Sunnyvale, CA (US)

Correspondence Address: APPLIED MATERIALS, INC., 2881 SCOTT BLVD. M/S 2061, SANTA CLARA, CA, 95050, US

(73) Assignee: Applied Materials, Inc.

(21) Appl. No.: 09/846,742

(22) Filed: May 1, 2001

(51) Int. Cl. C23C 14/34; B23K 20/08; B23K 28/00; B23K 35/36

(52) U.S. Cl. 204/298.12; 204/298.13; 204/298.11; 228/193; 228/107; 228/262.9

(57) ABSTRACT

A target assembly for a physical vapor deposition system having a target material flux region which produces backscatter particles and a substrate support assembly is provided. In one embodiment, the target assembly comprises a central region and a flange radially extending from the central region. The flange is constructed of a first material and is adapted to support the target assembly within the physical vapor deposition system in a parallel spaced apart relation to the substrate support assembly. A flange cover member is disposed between the flange and the flux region. The flange cover member is constructed of a material having a greater adhesiveness to the backscatter particles than the first material and is permanently secured to the flange. A target member constructed of a sputterable material is disposed between the central region of the target assembly and the flux region of the physical vapor deposition system.

### BACKGROUND OF THE INVENTION

1. Field of the Invention

The invention relates to a physical vapor deposition system and, more particularly, to an improved target for improving particle performance within such a system.

2. Description of the Related Art

In semiconductor processing, and more specifically in physical vapor deposition, a target is typically disposed on a backing plate in the upper portion of a chamber. A plasma is struck between a work piece and the target to produce ions which bombard the target and result in the deposition of target material onto the work piece. While most processes are finely tuned to result in deposition of target material onto the work piece in a trajectory which is generally directed toward the work piece, some particles are redeposited on or near the target itself. These particles can become a source of contamination by loosely adhering to the target and surrounding areas of the chamber and may eventually flake off and fall onto the work piece.

Efforts aimed at reducing the concentration of particles in sputter chambers have taken many different approaches. One method involves the use of sputter shields that inhibit sputtered particles from depositing directly on the chamber walls. The sputter shield is often periodically replaced as part of a process kit so that buildup of potentially harmful deposits can be minimized. This method can reduce the frequency at which the chamber is cleaned. However, a fraction of the particles often pass around the shield and form undesirable deposits.

The problem of redeposition of sputtered material back onto the target sidewall has also been recognized as an undesirable source of particles in the chamber. Sputtered particles that become scattered in the chamber atmosphere can redeposit onto the side of the target and accumulate to form particles of the deposition material. Because RF or DC power is applied to the target during sputter deposition on a substrate and then removed from the target between substrates, the target, as well as the redeposited material, is often alternatively heated and cooled and thereby subjected to thermal stress. Over a period of time, this stress can cause particles of the redeposited material to come loose and fall onto the substrate.

The target in a physical vapor deposition system is typically attached to a back plate which serves as a lid to the deposition chamber. The portion of the back plate surrounding the outer perimeter of the target is an area in which back sputtered particles tend to deposit, and then, over time, fall to deposit on the substrate.

Therefore, there exists a need for an improved target that reduces the deposition of material in the gap between the shield and the target.

### SUMMARY OF THE PREFERRED EMBODIMENTS

A target assembly for a physical vapor deposition system having a target material flux region which produces backscatter particles is provided. In one embodiment, a backing member is constructed of a first material and has a central region and a flange radially extending from the central region. The backing member is adapted to support the target assembly within the physical vapor deposition system. A flange cover member is disposed between the flange and the flux region. The flange cover member is constructed of a second material preferably having a greater adhesiveness to the backscatter particles than the first material. The flange cover member is preferably permanently secured to the flange. A target member is disposed between the central region and the flux region and is constructed of a sputterable material.

In one aspect, the flange cover member is permanently secured to the flange by diffusion bonding, soldering, brazing, explosion bonding, friction welding, or roll bonding.

In another aspect, the flange cover member and the backing plate have a joint which is adapted to be exposed to portions of the physical vapor deposition system and the target assembly other than the flux region.

In yet another aspect, the first material is copper and the second material is aluminum.

### BRIEF DESCRIPTION OF THE DRAWINGS

FIG. 1 is a cross-sectional view of a known physical vapor deposition system.

FIG. 2 is a cross-sectional view of a known arrangement for a portion of a physical vapor deposition system comprising a target assembly, a shield, and a housing.

FIG. 3 is a cross-sectional view of a known target assembly for use in a physical vapor deposition system.

FIG. 4 is a cross-sectional view of a target assembly for use in a physical vapor deposition system in accordance with one embodiment of the present invention.

FIG. 5 is a cross-sectional view of a physical vapor deposition system in accordance with one embodiment of the present invention.

FIG. 6 is a cross-sectional view of a target stock piece for use in the manufacture of a target assembly in accordance with one embodiment of the present invention.

FIG. 7 is a cross-sectional view of a target assembly for use in a physical vapor deposition system in accordance with another embodiment of the present invention.

FIG. 8 is a cross-sectional view of a target assembly for use in a physical vapor deposition system in accordance with yet another embodiment of the present invention.

### DETAILED DESCRIPTION OF THE PREFERRED EMBODIMENTS

In the following description, reference is made to the accompanying drawings which form a part hereof and which illustrate several embodiments of the present invention. It is understood that other embodiments may be utilized and structural and operational changes may be made without departing from the scope of the present invention.

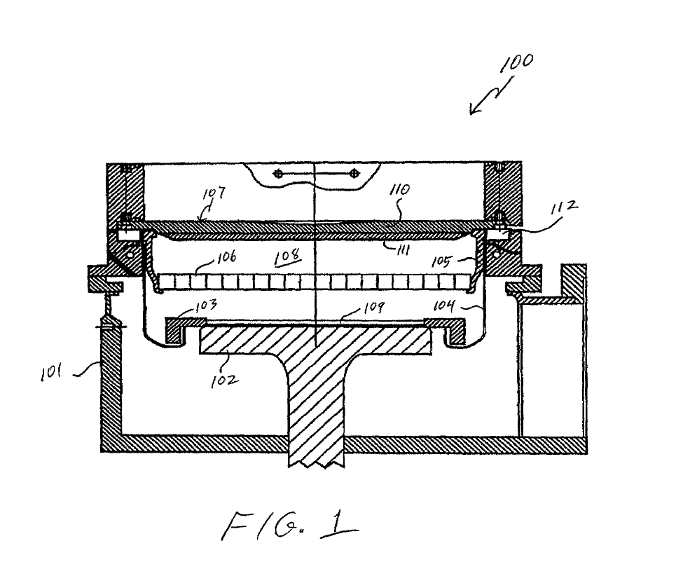

FIG. 1 depicts a simplified, cross-sectional view of a known, conventional physical vapor deposition (PVD) system 100. The system contains, within a system housing 101, a substrate support assembly 102, a shield ring 103, a plasma shield 104, a dark space shield 105, a collimator 106, and a target assembly 107. These elements of the PVD system are conventionally arranged within the housing 101. When a gas, such as argon, is pumped into a region 108 and high voltage is applied between the target assembly 107 and the substrate support 102, the argon forms a plasma within the region 108. The plasma sputters the target material which ultimately is deposited upon a substrate 109.

The target assembly 107 is fabricated of a backing plate 110 (typically copper or aluminum) which is diffusion bonded to a target member 111 constructed of a target material to be sputtered (e.g., titanium). Besides the foregoing target, other target designs are used in the art. For example, the target backing plate may be cup or dish shaped, i.e., having a hollow center, rather than a solid plate.

The dark space shield 105, besides supporting the collimator 106, also shields the backing plate 110 from being sputtered. Sputtering the backing plate would generate particles of the backing plate material which could contaminate the substrate. In general, it is often preferred that only the target layer be sputtered and not the backing plate material. The dark space shield therefore may be positioned in close proximity (approximately 0.065 inches) to the target. Such a small gap inhibits the plasma from leaking into the gap and sputtering the backing plate.

The target assembly 107 is maintained in a spaced-apart relation relative to the dark space shield by an insulator ring 112. Although the dark space shield and the target are near enough to one another to inhibit or prevent the plasma from sputtering the backing plate 110, the gap is often large enough to permit sputtered material from the target member 111 to enter the gap and deposit upon portions of the backing plate 110 and the side wall of the target member 111. This phenomenon is known in the art as backscatter deposition. Deposition in the gap can occur for particles having trajectories that are on a line-of-sight path with the backing plate and target layer edge.

Deposition onto portions of the backing plate 110 and the side wall of the target member 111 can be detrimental to a PVD process. For example, the deposition upon the side wall of the target member and certain portions of the backing plate often occurs along an oblique angle to these surfaces. When the temperature of the target changes and causes the target to expand or contract, the deposited material (or portion thereof) can dislodge from the surface and fall upon the substrate thus contaminating it.

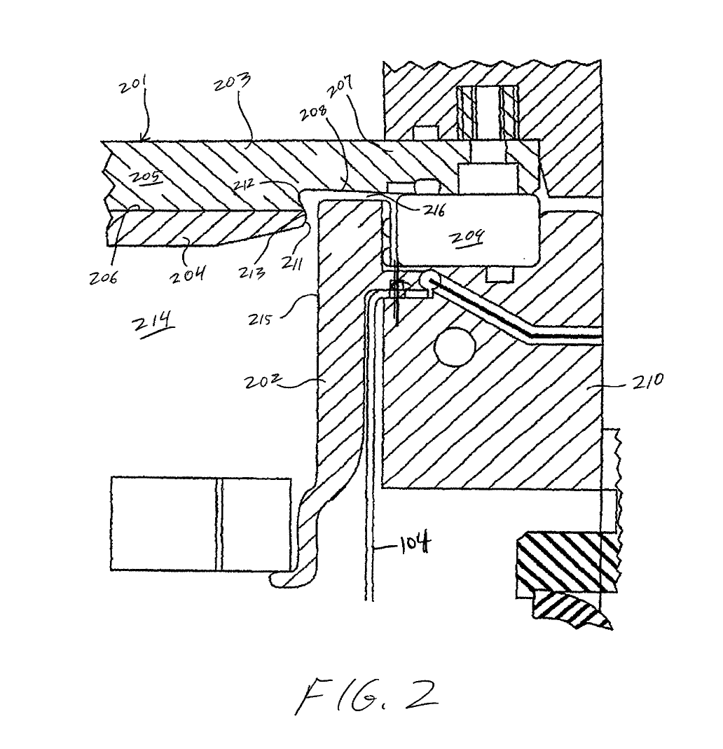

FIG. 2 depicts a target assembly 201 and dark space shield 202 for a PVD system, as disclosed in U.S. Pat. No. 5,658,442 which is assigned to a common assignee. To reduce the deposition of sputtered particles upon the side wall of the target assembly, a portion 211 of the target assembly side wall shadows the side wall of the target. To further lessen the deposition in the gap between the dark space shield and the target assembly, the dark space shield has a vertical inner surface.

The target assembly 201 contains a backing plate 203 having a target member 204 diffusion bonded upon its surface. The backing plate 203 is typically formed of copper or aluminum and the target member 204 is typically formed of a deposition material such as titanium, aluminum, copper, tantalum or some other sputterable material. The backing plate 203 has a central area 205 that contains a surface 206 upon which the target member 204 is bonded. From this central area of the backing plate extends a target support flange 207 having a generally horizontal target support surface 208. The target support surface 208 is a surface which potentially could be exposed to a reaction or flux region 214. The support surface 208 abuts and rests upon an insulator ring 209 that also forms a seal between the target and a system housing 210.

By maintaining a gap 216 between the support surface 208 and the dark space shield 202 with a spacing of less than 0.080 inches, very little or no plasma should leak into the gap 216 and sputter the backing plate. Moreover by having an inner surface 215 of the dark space shield 202 that is orthogonal to the target support surface 208, partial deposition on the side walls 212 and 213 of the target assembly 201 can be reduced.

The target assembly 201 includes a corner 211 which overhangs and shadows the side wall of the target, e.g., a side wall 212 of the central region 205 of the backing plate 203 and a side wall 213 of the target member 204 (cumulatively referred to as the target edge). With this geometry, particles within the flux region 214 are less likely to have a line of sight trajectory that impacts the target edge. Thus, oblique angle impacts are reduced or eliminated. Particles may still enter the gap along a vertical path. However, they will tend to impact the support surface 208 at a perpendicular angle of incidence. Generally, a perpendicular angle of incidence is more adhesive than an oblique angle of incidence.

It has been observed that the degree of particle adhesiveness varies with the type of material used for a backing plate. Typically, target assemblies are comprised of target members which are secured to backing plates of different materials in order to reduce target assembly costs or increase target strengths. Materials which have been used for backing plates include aluminum and copper. Aluminum has been found to have better adhesiveness for backscatter particles as compared with copper. To minimize substrate contamination therefore, it would be preferable to use aluminum. On the other hand, other materials, such as copper, have been found to have better strength and rigidity characteristics as compared with aluminum. Therefore for those reasons, copper would be a preferable back plate material. In the past, the selection of target materials has been more difficult by these conflicting goals.

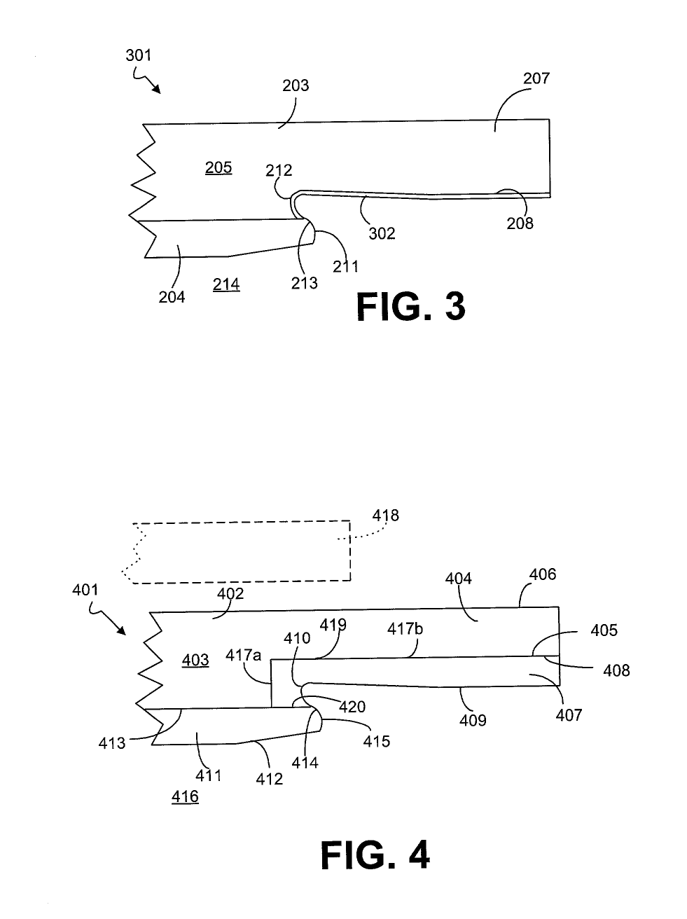

FIG. 3 illustrates a target assembly 301 which represents a known structure that employs a plurality of back plate materials. The target assembly 301 has a similar geometry as the target assembly 201 of FIG. 2. However the target assembly 301 of FIG. 3 further includes a thin coating 302 of aluminum which covers the support surface 208 of the support flange 207 which may be exposed to a flux region 214 and extends to the backing plate side wall 212. The aluminum coating 302 is typically applied by arc spraying or flame spraying aluminum onto the support surface 208 and side wall 212. Thus by having this coating 302 on the backing plate 203, increased adhesiveness for backscatter particles can be realized while the greater strength and rigidity of copper may also be realized.

One problem with this structure, however, concerns the interface between the aluminum coating 302 and the backing plate 203. A flame spraying or arc spraying application technique may not allow for an adequate level of control of the aluminum/copper interface. Certain sections of the interface may contain a relatively thick coating of aluminum whereas other sections may have an unacceptably thin coating or no coating of aluminum at all. Moreover such aluminum application methods may not be acceptably reproduceable. That is, the production of a plurality of targets under this method may result in targets which vary from one to another in the nature of the aluminum coating.

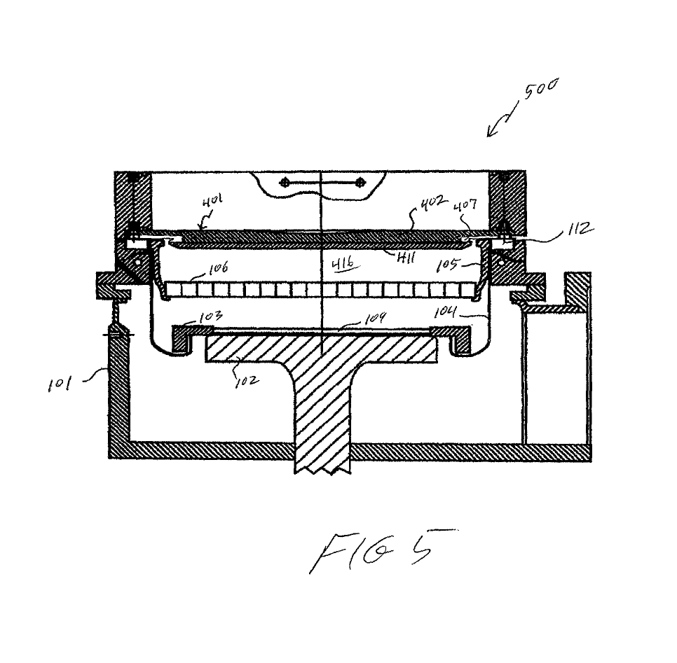

FIGS. 4 and 5 depict an improved target structure in accordance with one embodiment of the present invention. A target assembly 401 includes a backing plate 402 having a central area 403 and an annular shaped recess 419 which defines a support flange 404 extending from the central area 403. The backing plate 402 is constructed of copper or any other material which preferably has relatively high strength and rigidity characteristics. The support flange 404 has a proximate side 405 which is disposed closest to a PVD system flux region 416 and a distal side 406. Adjacent to the target assembly 401 is a magnetron 418 for creating a plasma in the flux region 416 disposed on the opposite side of the assembly 401.

A flange cover member 407 is provided which is constructed of aluminum or any other material which preferably has relatively high adhesion characteristics for backscatter particles. The flange cover member 407 is annular-shaped in the illustrated embodiment and is received in the backing plate recess 419 so that it abuts the central area 403 of the backing plate and further abuts the proximate side 405 of the support flange 404. Thus a joint 417a is defined by the abutment of the flange cover member 407 with the central area 403 of the backing plate 402, and a joint 417b is defined by the abutment of the support flange 404 with the flange cover member 407. The flange cover member 407 is permanently affixed to the central area 403 and the proximate side 405 of the flange 404 such that the joint 417a, 417b is formed by diffusion bonding, or alternatively, by other permanent bonding techniques including soldering, brazing, explosion bonding, friction welding or roll bonding. A permanent attachment is desirable in that it may provide superior heat transfer characteristics between the flange cover member 407 and the flange 404 through the joint 417a, 417b as compared with attachment techniques which are removable.

The flange cover member 407 has a distal side 408 which, as previously described, abuts the proximate side 405 of the support flange 404, and a proximate side 409 which generally faces the flux region 416. Thus although the proximate side 405 of the flange 404 might otherwise be exposed to the flux region 416, the placement of the flange cover member 407 in the manner described above preferably entirely covers the proximate side 405 of the flange 404 so that no part of it in fact will be exposed to the flux region 416. The proximate side 409 of the flange cover member 407 is a generally horizontal support surface for the target assembly 401. The portion 420 of the proximate side 409 which is closest to the central area 403 of the backing plate 402 forms a concave-shaped side wall 410 spaced apart from the joint 417a. The permanent attachment of the flange cover member 407 to the flange 404, as previously described, may be further advantageous over removable attachment techniques in that better manufacturing tolerances between the proximate side 409 and the concave-shaped side wall 410 of the cover member 407, on the one hand, and the inner surface of a dark space shield (such as that shown at reference numeral 215 of FIG. 2), on the other hand, may be maintained.

The target assembly 401 further includes a target member 411 having a proximate side 412 which faces the flux region 416 and a distal side 413. A portion of the distal side 413 abuts and is secured to the central area 403 of the backing plate 402. The remaining portion of the distal side 413 abuts and is secured to the portion 420 of the proximate side 409 of the flange cover member 407 adjacent to the side wall 410. The target member 411 therefore covers that part of the joint 417a which otherwise would be exposed to the flux region 416. Thus no portion of the joint 417a, 417b is exposed to the flux region 416. This is desirable in that the exposure of such a joint may cause backscatter particles to loosely adhere to the joint area which in turn can increase the risk of substrate contamination. The edge of the target member 411 terminates in a convex-shaped side wall 414. The target member side wall 414 is aligned with the aluminum member side wall 410 so that a corner 415 is formed. The corner 415 overhangs and shadows the side walls 414 and 410 in the same manner as is described in FIG. 2, reference numeral 211. However in the embodiment of FIG. 4, no portion of the backing plate 402 is exposed to the flux region 416.

By use of an aluminum member piece, such as that shown at reference numeral 407, the disadvantages of a flame or arc sprayed coating are avoided. An aluminum member piece provides a more uniform layer of aluminum on the support flange 404 onto which back scatter particles may attach. Yet the strength of a backing plate manufactured from a stronger metal, such as copper, may still be realized. Moreover, manufacturing variations among the resulting targets should be reduced.

As best seen in FIG. 5, the target assembly 401 is placed in the housing 101 of a PVD system 500 in a parallel, spaced-apart relation to the substrate 109. The cover member 407 forms a complete barrier between the backing plate 402 and the flux region 416, thus providing a target assembly having both a strong back plate 402 and a surface having a high adhesion to backscatter particles.

It should be appreciated that a target assembly in accordance with the present inventions may be used in a variety of sputtering chambers in which various components including shields, collimators and chucks may vary, depending upon the application. Indeed, some of these components may not be needed in some applications. In addition, the chamber may optionally use one or more of a variety of plasma generating apparatus including coils, electrodes, electron guns and waveguides.

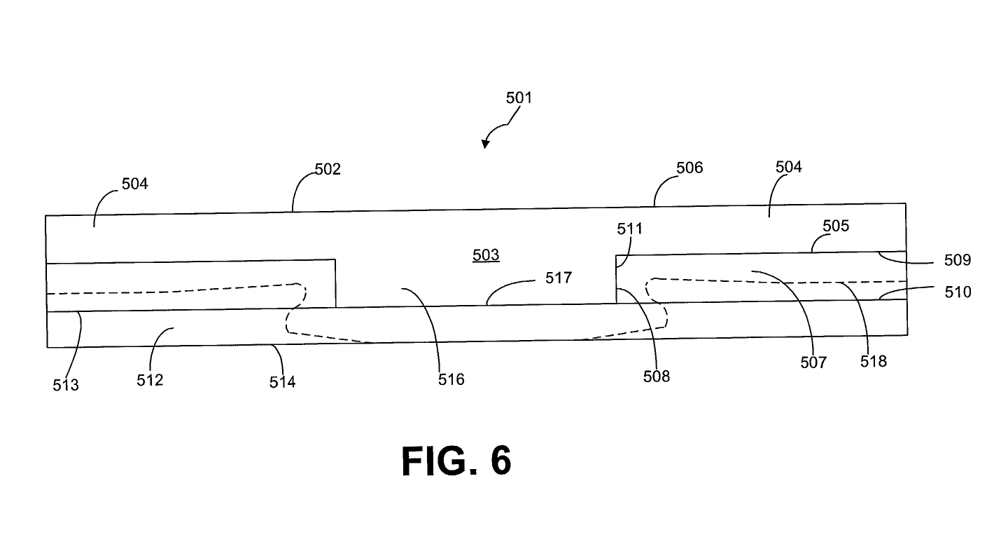

FIG. 6 shows one manner in which the target assembly 401 of FIGS. 4 and 5 can be constructed. A target stock piece 501 is comprised of three components: a backing plate 502, a flange cover member 507, and a target member 512. The backing plate 502 is circular-shaped and has a distal side 506, a central area 503 and a support flange 504 extending from the central area 503. The backing plate 502 is constructed of copper or any other material of relatively high strength or rigidity properties. The central area 503 is defined by a cylindrically-shaped extension 516 which is centered on the axis of the backing plate 502 and which extends axially from the side of the backing plate 502 which is opposite the distal side 506. The extension 516 has a side wall 511 and a proximate side 517 which is generally parallel to the backing plate distal side 506. The support flange 504 has a proximate side 505 which is orthogonal to the side wall 511 and which is parallel to the backing plate distal side 506.

The annular-shaped flange cover member 507 has an opening 508 centered on the axis of the flange cover member 507. The flange cover member 507 is constructed of aluminum or any other material having a relatively high degree of adhesiveness to backscatter particles. The flange cover member 507 has a distal side 509 which abuts and is permanently affixed to the proximate side 505 of the support flange 504 by welding, diffusion bonding or the like. The opening 508 is sized to mate with the side wall 511 of the extension 516. A proximate side 510 of the flange cover member 507 is disposed opposite to that of its distal side 509. The thickness of the flange cover member 507 is approximately the same as the length of the backing plate extension side wall 511 so that when these two pieces are mated, the extension proximate side 517 and the flange cover member proximate side 510 are aligned to form a generally planar surface.

A disc-shaped target member 512 has a proximate side 514 and a distal side 513. The target member 512 is constructed of titanium or any other sputterable material. The target distal side 513 abuts and is attached to the proximate side 510 of the flange cover member 507 and to the proximate face 517 of the backing plate extension 516 by diffusion bonding or other attachment methods. The target member proximate side 514 is opposite that of its distal side 513 so that when the backing plate 502, the flange cover member 507 and the target member 512 are attached together, the target stock piece 501 is formed as a solid disc. Using a computer numerically controlled (cnc) lathe or other machine tool, portions of the target member 512 and if desired, the flange cover member 507 can be removed from the target stock piece 501 to expose the flange cover member 507 and to shape the piece 501 into a finished target of any desired geometry. In FIG. 5, dotted line 518 represents a cut line which could be made to form the target assembly 401 of FIG. 4. In the illustrated embodiment, the flange cover member preferably has a thickness, once completed, of at least 1 mm to full flange thickness, and more preferably 5 mm.

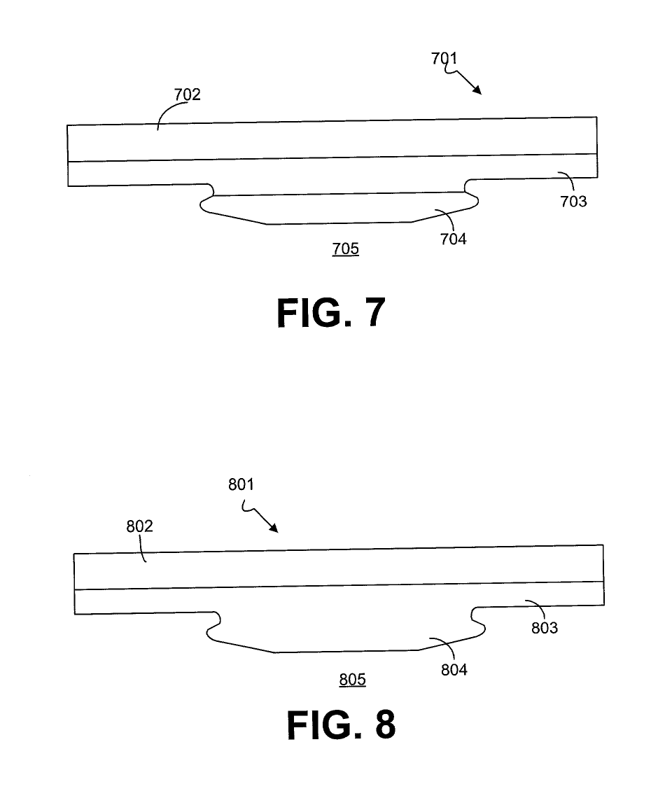

The target design of FIGS. 4-6 incorporate a backing plate having a central area which extends axially from the center of the plate and which abuts a target member. In FIG. 7 a multi-material target assembly 701 of an alternative design is disclosed. The target assembly 701 has a backing plate 702 manufactured from a relatively strong material such as copper. The backing plate is cylindrical in shape and does not have a central area extending axially from the center of the plate. Rather, a cover member 703 manufactured from a second material having relatively high adhesion characteristics to backscatter particles (such as aluminum) is disposed between the backing plate 702 and a flux region 705 so that no portion of the backing plate 702 is exposed to the flux region 705. A target member 704 made of a sputterable material such as tungsten abuts and is secured to the cover member 703. Thus the cover member 703 separates the target member 704 from the backing plate 702 so that no portion of the target member 704 is in contact with the backing plate 702.

It should be appreciated that there are materials which can be selected for a cover member which can both be a sputterable material and can have relatively high adhesion characteristics for backscatter particles. A material such as aluminum can have both characteristics. Referring to FIG. 8, a target assembly 801 is comprised of two materials. A backing plate 802 is made of a relatively strong material such as copper. A cover member 803 is disposed between the backing plate 802 and a flux region 805 so that no portion of the backing plate 802 is exposed to the flux region 805. The cover member 803 is made of a sputterable material which also has relatively high adhesion characteristics for backscatter particles. One such material could be aluminum. The cover member 803 has a target region 804 which is generally cylindrical in shape and which extends axially from the center of the cover member 803 toward the direction of the flux region 805.

Additionally, the particular target designs shown and described herein should be considered illustrative rather than limiting the invention to a specific type or style of target. Other target styles such as dish or cup-shaped targets would also benefit from the present invention.

While the description above refers to particular embodiments of the present invention, it will be understood that many modifications may be made without departing from the spirit thereof. The accompanying claims are intended to cover such modifications as would fall within the true scope and spirit of the present invention. The presently disclosed embodiments are therefore to be considered in all respects as illustrative and not restrictive, the scope of the invention being indicated by the appended claims rather than the foregoing description, and all changes which come within the meaning and range of equivalency of the claims are therefore intended to be embraced therein.

What is claimed is:

1. A target assembly for a physical vapor deposition system having a target material flux region which produces backscatter particles, the target assembly comprising:
a backing member constructed of a first material and having a central region and a flange radially extending from the central region and being adapted to support the target assembly within the physical vapor deposition system;
a flange cover member disposed between the flange and the flux region, the flange cover member being constructed of a second material having a greater adhesiveness to the backscatter particles than the first material, the flange cover member being permanently secured to the flange; and
a target member disposed between the central region and the flux region, the target member being constructed of a sputterable material.

2. The target assembly of claim 1 wherein the flange cover member is permanently secured to the flange by one of diffusion bonding, soldering, brazing, explosion bonding, friction welding, and roll bonding.

3. The target assembly of claim 1 wherein the flange cover member and the backing plate have a joint which is adapted to be exposed to portions of the physical vapor deposition system and the target assembly other than the flux region.

4. The target assembly of claim 1 wherein the first material is copper and the second material is aluminum.

5. An apparatus for a physical vapor deposition system comprising:
a housing;
a substrate support assembly;
a target material flux region which produces backscatter particles;
a target assembly comprising:
a backing member constructed of a first material and having a central region and a flange radially extending from the central region and being adapted to support the target assembly within the physical vapor deposition system;
a cover member disposed between the flange and the flux region, the cover member being constructed of a second material having a greater adhesiveness to the backscatter particles than the first material, the cover member being permanently secured to the flange; and
a target member disposed between the central region and the flux region, the target member being constructed of a sputterable material;
an insulative member electrically isolating the target assembly from the anode; and
a shield disposed between the target member and the insulative member.

6. The apparatus of claim 5 wherein the cover member is permanently secured to the flange by one of diffusion bonding, soldering, brazing, explosion bonding, friction welding, and roll bonding.

7. The apparatus of claim 6 wherein the cover member and the backing plate have a joint which is adapted to be exposed to portions of the deposition system and the target assembly other than the flux region.

8. The apparatus of claim 7 wherein the first material is copper and the cover member is constructed of aluminum.

9. A method of manufacturing a target assembly for use in a physical vapor deposition system having a target material flux region which produces backscatter particles, the method comprising:
permanently affixing a generally disc-shaped backing plate member having a proximate side and a distal side to a generally disc-shaped cover member having a proximate side and a distal side;
the proximate side of the backing plate having a generally cylindrically-shaped extension portion centered on the axis of the backing plate and extending axially from the backing plate proximate side;
the cover member having an opening centered on the axis of the cover member, the opening being adapted to mate with the extension portion of the backing plate;
the proximate side of the backing plate member abutting the distal side of the cover member;
the proximate side of the cover member and the extension portion of the backing plate being adapted to form a generally planar surface;
the cover member being made of a material having a greater adhesiveness to the backscatter particles than the backing plate member;
affixing one side of a generally disc-shaped target member to the generally planar surface formed by the proximate side of the cover member and the extension portion of the backing plate to form a target stock piece; and
machining the target stock piece to form a target assembly adapted for use in the physical vapor deposition system, the target assembly having a portion of the cover member adapted to being exposed to the flux region.

10. The method of claim 9 wherein the cover member is permanently affixed to the backing plate member by one of diffusion bonding, soldering, brazing, explosion bonding, friction welding, and roll bonding.

11. The method of claim 9 wherein the cover member and the backing plate member have a joint which is adapted to be exposed to portions of the deposition system and the target assembly other than the flux region.

12. The method of claim 9 wherein the backing plate member is constructed of copper and the cover member is constructed of aluminum.

13. A target assembly for a physical vapor deposition system having a target material flux region which produces backscatter particles, the target assembly comprising:
a backing member constructed of a first material and being adapted to support the target assembly within the physical vapor deposition system;
a cover member disposed between the backing member and the flux region so that no portion of the backing member is exposed to the flux region, the cover member being constructed of a second material having a greater adhesiveness to the backscatter particles than the first material, the cover member being permanently secured to the backing member; and
a target member constructed of a sputterable material and disposed between the cover member and the flux region, the target member being permanently secured to the cover member.

14. The target assembly of claim 13 wherein the cover member is permanently secured to the backing plate by one of diffusion bonding, soldering, brazing, explosion bonding, friction welding, and roll bonding.

15. The target assembly of claim 13 wherein the cover member and the backing plate have a joint which is adapted to be exposed to portions of the physical vapor deposition system and the target assembly other than the flux region.

16. The target assembly of claim 13 wherein the first material is copper and the second material is aluminum.

17. A target assembly for a physical vapor deposition system having a target material flux region which produces backscatter particles, the target assembly comprising:
a backing member constructed of a first material and being adapted to support the target assembly within the physical vapor deposition system;
a cover member disposed between the backing member and the flux region so that no portion of the backing member is exposed to the flux region, the cover member being constructed of a sputterable material having a greater adhesiveness to the backscatter particles than the first material, the cover member being permanently secured to the backing member and having a target region extending axially from the center of the cover member in the direction of the flux region.

18. The target assembly of claim 17 wherein the cover member is permanently secured to the backing plate by one of diffusion bonding, soldering, brazing, explosion bonding, friction welding, and roll bonding.

19. The target assembly of claim 17 wherein the cover member and the backing plate have a joint which is adapted to be exposed to portions of the physical vapor deposition system and the target assembly other than the flux region.

20. The target assembly of claim 17 wherein the first material is copper and the cover member is constructed of aluminum.
